(19) United States
(12) Patent Application Publication
(10) Pub. No.: US 2008/0135798 A1
(43) Pub. Date: Jun. 12, 2008

(54) Nano-Size Lead-Free Piezoceramic Powder and Method of Synthesizing the Same

(76) Inventors: Jae Ho Jeon, Changwon-si (KR); Jung Yeul Yun, Changwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/939,630

(22) Filed: Nov. 14, 2007

(30) Foreign Application Priority Data
Dec. 7, 2006 (KR) 10-2006-0123978

(51) Int. Cl. H01L 41/187; B02C 17/00; C04B 35/495

(52) U.S. Cl. 252/62.9 R; 241/170; 423/594.8; 501/134

(57) ABSTRACT

A nano-size lead-free piezoceramic powder and a method of mechanochemically synthesizing the same are provided. The nano-size lead-free piezoceramic powder can have a basic component of (KₓNa₁₋ₓ)NbO₃, where x ranges from 0 to 1. A weight ratio of a milling ball to a raw powder can be set, and then the milling ball and the raw powder can be provided into a milling container at the set ratio. Nano-size lead-free piezoceramic powder can be mechanochemically synthesized using a high-energy ball mill device.

### CROSS-REFERENCE TO RELATED APPLICATION

The present application claims the benefit under 35 U.S.C. § 119 to Korean Patent Application No. 10-2006-0123978, filed Dec. 7, 2006, which is hereby incorporated by reference in its entirety.

### BACKGROUND

In general, piezoceramics generate a voltage when pressure is applied and undergo a mechanical shape change when an electric field is applied. Also, piezoceramics are materials in which conversion between mechanical and electrical energies is highly efficient.

Piezoceramics are used in various industrial fields. Particularly, the use of piezoceramics is increasing in fields such as electronic devices, medical equipment, and military supplies. Representative examples of the use of piezoceramics include a medical ultrasonic sensor, a precise position controller, a piezo pump and valve, and various actuators.

However, because the currently-used piezoceramics are tertiary or quaternary ceramics, such as Pb(Zr,Ti)O₃-based compositions or Pb(Mg_{1/3}Nb_{2/3})TiO₃-based compositions, which contain lead as a main element, these piezoceramics can cause serious problems. For example, in a process of fabricating the piezoceramics, a large amount of PbO is volatilized, which creates environmental pollution. Also, discarded components containing piezoceramics may cause ground pollution and water pollution, which results in lead poisoning in the human body.

Therefore, it is necessary to substitute the existing lead-based piezoceramics with lead-free piezoceramics to avoid use of lead that is harmful to the human body and the environment.

There are several methods of fabricating lead-free piezoceramics. Examples of these methods are disclosed in Korean Patent Laid-Open Publication No. 10-2004-0054965 and Japanese Patent Laid-Open Publication No. 2006-06260. In each of the two publications, a mixture of raw powder is ground/calcined to fabricate a first powder, and then the primary powder is ground/calcined to fabricate a phase-synthesized second powder. Also, in Japanese Patent Laid-Open Publications Nos. 2000-31664 and 2004-115293, a method of developing a composition of lead-free piezoceramics and adding a sintering aid such as CuO to increase a sintering property is disclosed.

However, all of the above methods inevitably require a calcining process performed at a high temperature ranging from 600° C. to 1000° C. to synthesize the lead-free piezoceramic powder. Thus, the powder synthesized by the high-temperature calcining process necessarily has a size greater than hundreds of nanometers.

Consequently, the methods cannot be used to synthesize piezoceramic powder having a size on the order of tens of nanometers or less.

Also, to obtain a high-density sintered compact, the sintering temperature must be increased or a sintering aid, such as CuO, must be added. However, the amount by which the sintering temperature may be increased is limited because a high sintering temperature may cause volatilization of elements having high volatility such as Na and K. Thus, the characteristics of the piezoceramics may be deteriorated.

### BRIEF SUMMARY

The present invention is directed to a nano-size lead-free piezoceramic powder and a method of synthesizing the same that substantially obviates one or more limitations and disadvantages of the related art.

Embodiments of the present invention provide a nano-size lead-free piezoceramic powder that has a basic composition of (KₓNa₁₋ₓ)NbO₃, where x ranges from 0 to 1, can be synthesized by a mechanochemical method using a high-energy ball mill device, and thus can improve the sintering density even at a low sintering temperature in a subsequent sintering process.

Another embodiment of the present invention provides a method of mechanochemically synthesizing nano-size lead-free piezoceramic powder.

Additional features of the present invention will be set forth, in part, in the description which follows and, in part, will become apparent to those having ordinary skill in the art upon examination of the following or may be learned from practice of the invention.

To achieve embodiments of the present invention, as exemplified and broadly described herein, a method of mechanochemically synthesizing nano-size lead-free piezoceramic powder having a basic component of (KₓNa₁₋ₓ)NbO₃, where x ranges from 0 to 1, is provided. In an embodiment, the method can include: setting a weight ratio of a milling ball to a raw powder; providing the milling ball and the raw powder into a milling container at the weight ratio; and mechanochemically synthesizing the nano-size lead-free piezoceramic powder using a high-energy ball mill device.

Also, materials of a milling ball and a milling container of a high-energy ball mill device, as well as the milling time, can be controlled, so that lead-free piezoceramic powder of a size on the order of tens of nanometers or less can be synthesized without a heat treatment such as a calcining process. Controlling the materials and milling time can also be lead to the synthesis of lead-free piezoceramic powder with various compositions.

The nano-size lead-free piezoceramic powder can have improved characteristics because a sintering temperature in a subsequent sintering process can be lowered and, thus, volatilization of elements having strong volatility such as Na and K, which can be present in the lead-free piezoceramic powder, can be minimized.

It is to be understood that both the foregoing general description and the following detailed description of the present invention are exemplary and are intended to provide further explanation of the invention as claimed.

### BRIEF DESCRIPTION OF THE DRAWINGS

FIG. 1 is a graph showing synthesis behavior as a function of milling time in mechanochemically synthesizing NaNbO₃, a nano-size lead-free piezoceramic powder, according to an embodiment of the present invention.

FIG. 2 is an electron microscope image showing a fine structure of NaNbO₃, which can be mechanochemically synthesized according to an embodiment of the present invention.

FIG. 3 is a graph showing synthesis behavior as a function of milling time when (K_{0.5}Na_{0.5})NbO₃, which is a nano-size lead-free piezoceramic powder, is mechanochemically synthesized according to an embodiment of the present invention.

FIG. 4 is an electron microscope image showing a fine structure of (K_{0.5}Na_{0.5})NbO₃ which can be mechanochemically synthesized according to an embodiment of the present invention.

### DETAILED DESCRIPTION

Reference will now be made in detail to the preferred embodiments of the present invention, examples of which are illustrated in the accompanying drawings. The invention may, however, be embodied in many different forms and should not be construed as being limited to the embodiments set forth herein.

In an embodiment of the present invention, KNN-based lead-free piezoceramic powder having a basic composition expressed as (KₓNa₁₋ₓ)NbO₃, where x ranges from 0 to 1, can be mechanochemically synthesized. First, raw powder can be weighed to a desired composition ratio and provided into a milling container. The mechanochemical synthesis can then be performed at or near room temperature using a high-energy ball mill device with a milling ball.

The high-energy ball mill device can be, for example, a vibratory/shaker mill, a planetary mill, or an attrition mill. In an embodiment, a shaker mill having a speed of about 900 rpm to about 1200 rpm can be used.

A shaker mill is a vibratory mill, which 3-dimensionally (3-D) vibrates in vertical and horizontal directions. During synthesis, the shaker mill can scatter and grind raw powder into nanoscale fine particles by 3-D vibration.

The high-energy ball mill device can include a milling container and a milling ball. The milling container and the milling ball can each be formed of, for example, a zirconia-based material, an iron-based material, or a tungsten carbide-based material. The milling container and the milling ball can be selected to be suitable for the type of input raw powder.

In an embodiment, a weight ratio of the milling ball to raw powder provided into the milling container can be from about 10:1 to about 50:1. The weight ratio can be set to a suitable value depending on material of the milling container, materials of the milling ball, and the type of raw powder.

If the weight ratio of the milling ball to the raw powder is less than about 10:1, the energy of collision between milling balls and the energy of collision between the milling ball and the milling container can become low during a ball-milling operation using the high-energy ball mill device. Thus, disadvantageously, the scattering and grinding effect of the raw powder can be deteriorated significantly. If the weight ratio of the milling balls to the raw powder is greater than about 50:1, the amount of raw powder provided into the milling container can be small, which can lead to an undesirable lowering of the probability that the raw powder is placed between the milling balls or between the milling ball and the milling container.

The milling time of the high-energy ball milling can vary based on the type of raw powder being used, the weight ratio between the milling ball and the raw powder, and the materials of the milling ball and the milling container. In an embodiment, high-energy ball milling by the high-energy ball milling device can be performed for at least about 10 minutes.

Raw powder and balls can be provided into the milling container of the high-energy ball milling device, and the ball milling can be performed without adding any separate liquid additive. Thus, in an embodiment, dry high-energy ball milling can be performed.

When the raw powder is provided into the milling container together with the milling ball, lithium (Li), magnesium (Mg), calcium (Ca), strontium (Sr), barium (Ba), lanthanum (La), silver (Ag), copper (Cu), arsenic (As), selenium (Se), bismuth (Bi), tantalum (Ta), antimony (Sb), titanium (Ti), tungsten (W), or any combination thereof can be added. In an embodiment, lead-free piezoceramic powder having a composition obtained by adding Li, Mg, Ca, Sr, Ba, La, Ag, Cu, As, Se, Bi, Ta, Sb, Ti, or W to the basic composition of KNN-based lead-free piezoceramic powder can be synthesized. Here, the basic composition of the KNN-based lead-free piezoceramic powder is (KₓNa₁₋ₓ)NbO₃, where x ranges from 0 to 1.

Examples of the present invention will now be described in detail. The following examples of the present invention are used only to describe the present invention, and it will be obvious to those skilled in the art that the scope of the present invention is not limited thereto.

### EXAMPLE 1

Na₂CO₃ and Nb₂O₅ are prepared as ceramic raw powder and weighed such that a composition of a compound synthesized after a reaction becomes NaNbO₃. Then, the resulting ceramic raw powder is placed in a zirconia-based milling container, together with tungsten carbide-based milling balls.

The weight ratio of the tungsten carbide-based milling ball to the ceramic raw powder is set to about 30:1. High-energy ball milling is performed by a shaker mill for about 20 hours, thereby fabricating nano-size NaNbO₃ by a mechanochemical reaction.

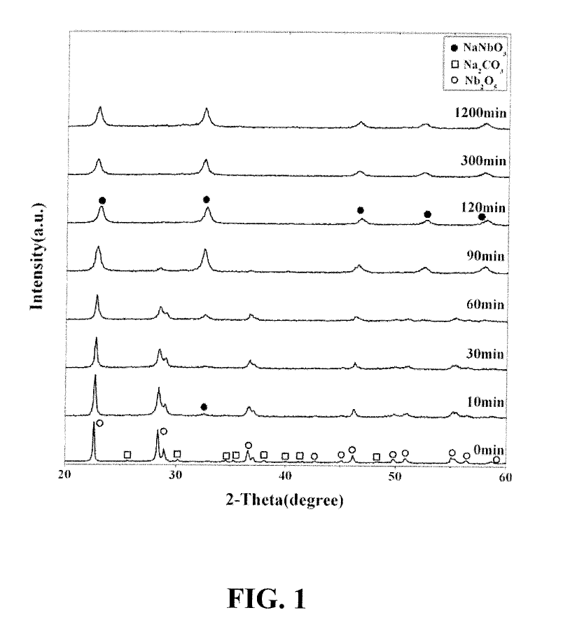

In FIG. 1, phase synthesis behavior over milling time is illustrated. Referring to FIG. 1, initial raw powder includes Na₂CO₃ and Nb₂O₅. Respective peaks representing Na₂CO₃ and Nb₂O₅ gradually decrease over milling time, while a peak representing NaNbO₃ being mechanochemically synthesized gradually increases. Thus, three phases exist at the same time after about one hour of the high-energy ball milling.

Most of the phases are synthesized into NaNbO₃ after about two hours of high-energy milling. Although the milling is performed for about 20 hours, no other phases are generated, and only NaNbO₃ phase exists.

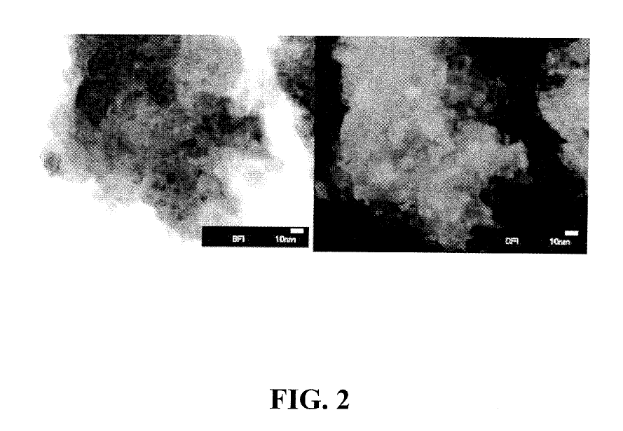

FIG. 2 illustrates an electron microscope image of lead-free ceramic powder synthesized mechanochemically through about two hours of high-energy ball milling. Referring to FIG. 2, the synthesized lead-free ceramic powder is formed as lumped particles that are each about 10 nanometers to about 20 nanometers in size.

### EXAMPLE 2

Na₂CO₃, K₂CO₃, and Nb₂O₅ are prepared as ceramic raw powder and weighed such that the composition of the compound synthesized after a reaction is (K_{0.5}Na_{0.5})NbO₃. Then, the resulting ceramic raw powder is placed in a zirconia-based milling container. Here, tungsten carbide-based milling balls are provided into the milling container, together with the ceramic raw powder.

The weight ratio of the tungsten carbide-based milling balls to the ceramic raw powder is set to about 30:1. The high-energy ball milling is then performed using a shaker mill for about 20 hours, thereby fabricating nano-size (K_{0.5}Na_{0.5})NbO₃ by a mechanochemical reaction.

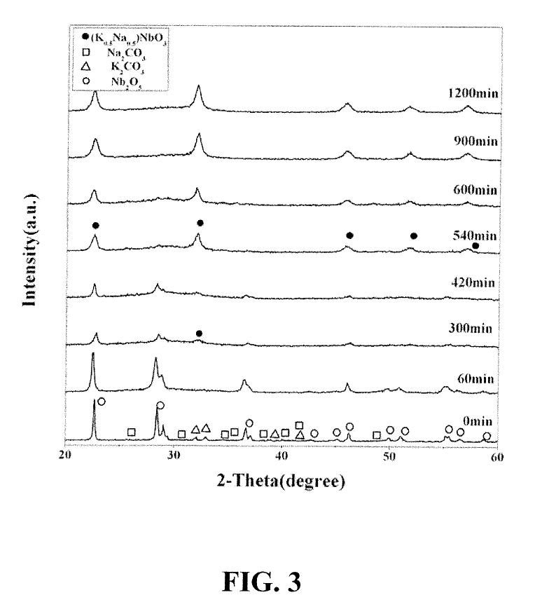

In FIG. 3, the phase synthesis behavior over milling time is illustrated. Referring to FIG. 3, initial raw powder includes K₂CO₃, Na₂CO₃, and Nb₂O₅, and respective peaks representing K₂CO₃, Na₂CO₃, and Nb₂O₅ gradually decrease over the milling time while a peak representing (K_{0.5}Na_{0.5})NbO₃ being mechanochemically synthesized gradually increases.

Most of the phases are synthesized into (K_{0.5}Na_{0.5})NbO₃ after about 9 to 10 hours of high-energy ball milling. Although the high-energy balling is performed for about 20 hours, no other phases are generated, and only the phase of (K_{0.5}Na_{0.5})NbO₃ exists.

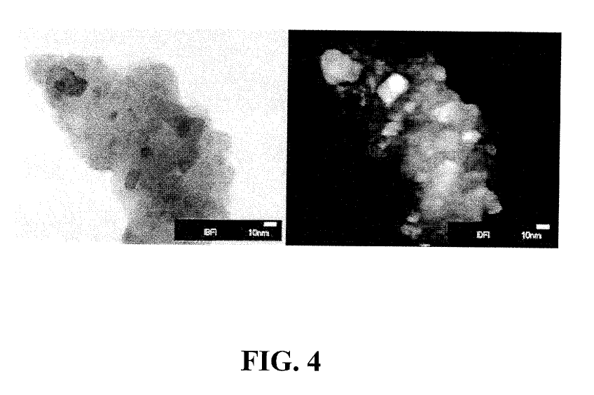

FIG. 4 illustrates an electron microscope image of powder that is synthesized mechanochemically through about 9 to 10 hours of high-energy ball milling. Referring to FIG. 4, the synthesized powder is formed as lumped particles that are each about 10 nanometers to about 20 nanometers in size.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of mechanochemically synthesizing a nano-size lead-free piezoceramic powder, comprising:
setting a weight ratio of a milling ball to a raw powder;
providing the milling ball and the raw powder into a milling container at the weight ratio; and
mechanochemically synthesizing the nano-size lead-free piezoceramic powder using a high-energy ball mill device;
wherein the nano-size lead-free piezoceramic powder comprises (KₓNa₁₋ₓ)NbO₃, where x ranges from 0 to 1.

2. The method according to claim 1, wherein the nano-size lead-free piezoceramic powder is mechanochemically synthesized at about room temperature.

3. The method according to claim 1, wherein mechanochemically synthesizing of the nano-size lead-free piezoceramic powder comprises performing dry high-energy ball milling.

4. The method according to claim 1, wherein the milling ball comprises a zirconia-based material, an iron-based material, or a tungsten carbide-based material.

5. The method according to claim 1, wherein the milling container comprises a zirconia-based material, an iron-based material, or a tungsten carbide-based material.

6. The method according to claim 1, wherein the high-energy ball mill device is a vibratory/shaker mill, a planetary mill, or an attrition mill.

7. The method according to claim 1, wherein the weight ratio of the milling ball to the raw powder is from about 10:1 to about 50:1.

8. The method according to claim 1, wherein the weight ratio of the milling ball to the raw powder is about 30:1.

9. The method according to claim 1, wherein before mechanochemically synthesizing the nano-size lead-free piezoceramic powder, lithium (Li), magnesium (Mg), calcium (Ca), strontium (Sr), barium (Ba), lanthanum (La), silver (Ag), copper (Cu), arsenic (As), selenium (Se), bismuth (Bi), tantalum (Ta), antimony (Sb), titanium (Ti), or tungsten (W) is added to the raw powder.

10. The method according to claim 1, wherein mechanochemically synthesizing the nano-size lead-free piezoceramic powder using a high-energy ball mill device is performed for about 20 hours.

11. A nano-size lead-free piezoceramic powder, comprising (KₓNa₁₋ₓ)NbO₃, where x ranges from 0 to 1; wherein the nano-size lead-free piezoceramic powder is synthesized by a method comprising:
setting a weight ratio of a milling ball to a raw powder;
providing the milling ball and the raw powder into a milling container at the weight ratio; and
mechanochemically synthesizing the nano-size lead-free piezoceramic powder using a high-energy ball mill device.

12. The nano-size lead-free piezoceramic powder according to claim 11, wherein the nano-size lead-free piezoceramic powder is mechanochemically synthesized at about room temperature.

13. The nano-size lead-free piezoceramic powder according to claim 11, wherein mechanochemically synthesizing of the nano-size lead-free piezoceramic powder comprises performing dry high-energy ball milling.

14. The nano-size lead-free piezoceramic powder according to claim 11, wherein the milling ball comprises a zirconia-based material, an iron-based material, or a tungsten carbide-based material.

15. The nano-size lead-free piezoceramic powder according to claim 11, wherein the milling container comprises a zirconia-based material, an iron-based material, or a tungsten carbide-based material.

16. The nano-size lead-free piezoceramic powder according to claim 11, wherein the high-energy ball mill device is a vibratory/shaker mill, a planetary mill, or an attrition mill.

17. The nano-size lead-free piezoceramic powder according to claim 11, wherein the weight ratio of the milling ball to the raw powder is from about 10:1 to about 50:1.

18. The nano-size lead-free piezoceramic powder according to claim 11, wherein the weight ratio of the milling ball to the raw powder is about 30:1.

19. The nano-size lead-free piezoceramic powder according to claim 11, wherein before mechanochemically synthesizing the nano-size lead-free piezoceramic powder, Li, Mg, Ca, Sr, Ba, La, Ag, Cu, As, Se, Bi, Ta, Sb, Ti, or W is added to the raw powder.

20. The nano-size lead-free piezoceramic powder according to claim 11, wherein mechanochemically synthesizing the nano-size lead-free piezoceramic powder using a high-energy ball mill device is performed for about 20 hours.
